(19) United States
(12) Patent Application Publication
(10) Pub. No.: US 2010/0007945 A1
(43) Pub. Date: Jan. 14, 2010

(54) Optical Device Comprising a GaInP-Based Photonic Crystal not Exhibiting Two-Photon Absorption

(75) Inventors: Sylvain Combrie, Paris (FR); Alfredo De Rossi, Paris (FR)

Correspondence Address: LARIVIERE, GRUBMAN & PAYNE, LLP, 19 UPPER RAGSDALE DRIVE, SUITE 200, MONTEREY, CA, 93940, US

(73) Assignee: Thales, Neuilly Sur Seine (FR)

(21) Appl. No.: 12/499,992

(22) Filed: Jul. 9, 2009

(30) Foreign Application Priority Data
Jul. 11, 2008 (FR) 08 03991

(51) Int. Cl. H01S 5/30; G02F 1/365; H04B 10/06

(52) U.S. Cl. 359/344; 250/551

(57) ABSTRACT

The invention relates to an optical device operating within a wavelength range centred on a reference wavelength (λ₀) and delivering an output signal, characterized in that it comprises a photonic crystal structure having a semiconductor substrate and at least one layer of semiconductor material having, at least locally, an array of features arranged so as to form a resonant optical cavity, said material of the semiconductor layer being a gallium/indium/phosphorus alloy not exhibiting two-photon absorption within the operating wavelength range of said device.

### PRIORITY CLAIM

This application claims priority to French Patent Application Number 08 03991, entitled Optical Device Comprising a GaInP-Based Photonic Crystal not Exhibiting Two-Photon Absorption, filed on Jul. 11, 2008.

### BACKGROUND OF THE INVENTION

The field of the invention is that of optical devices based on known photonic-crystal circuits for providing novel functions in the photonics field, in particular for all-optical signal processing and notably signal sampling. The specificity of this technology is the extreme compactness of the structures produced.

At the present time, integration of photonic components remains a very ambitious objective. In contrast with electronics, which experienced the transition from discrete component to integrated circuit a very long time ago, photonics are starting along the road towards integration.

Thus, the aim of the “silicon photonics” project is currently to transfer passive optical functions (optical waveguides, filters, etc.) and active optical functions (lasers) onto a silicon substrate.

More generally, recent advances in microfabrication (e-beam fabrication, novel etching techniques, etc.) have given rise to a variety of miniaturized optical components having remarkable properties (micromodulators, microsensors, nanolasers, etc.) opening the way to the next phase in which these components will be integrated so as to produce a complex optical function.

The advantage of integration is not so much in improving the performance of a component (for example a modulator or a laser), but rather in the prospect of reducing the footprint, weight, consumption and assembly complexity of discrete components when it is desired to produce a complex optical function.

Examples of complex optical functions may typically be the all-optical routing of information packets, or a sampling operation.

It is thus possible to organize the information routing by optical control on an optical carrier. Starting from a carrier emitting a signal at a wavelength λₛ, it is possible to make said signal wave interact with an optical control wave at a wavelength λ_{c} so as to address a packet of optical signal information corresponding to bit 3 or to bit 2 or to bit 1 or to bit 0, this also being called optical header recognition.

This type of application is based on a key function, namely an ultrafast optical “gate” which opens at a very precise instant, so as to recognize packet headers. Since the data rates in question are currently around 10-160 Gb/s, these “gates” must switch in less than 10 picoseconds, or even 1 picosecond. These speeds are achievable by exploiting the non-linear optical response.

To provide this type of function, it is necessary to use a material in which the propagation of the optical signals can generate non-linear effects, notably in terms of refractive index. Notably, the Kerr effect in materials exhibiting third-order non-linear effects may be exploited. In materials of this type, the phase of an optical wave varies with the power. To exploit an intensity variation and not a phase variation, it is known to use an interferometer, such as the one illustrated in FIG. 1.

Thus, the interaction of an optical carrier with a control signal within a material having a high non-linear coefficient χ³ enables the optical carrier to be sampled.

However, to obtain high performance, it is necessary that, within the non-linear material, absorption, notably two-photon absorption recognized in materials exhibiting useful properties in non-linear optics, remain negligible.

The problem thus addressed by the present invention is to have a non-linear response of the Kerr type (e.g. refractive index varying with optical power) without this being accompanied by 2-photon absorption, followed by generation of carriers and source of problems.

In this regard, materials such as silicon are unsuitable for ultrafast (few-picoseconds range) switching applications.

One solution in the literature consists in using direct-bandgap semiconductors (for example GaAs and its aluminium-based ternary derivatives), the objective being to set the energy of the bandgap at a value more than twice the energy of the photons involved in the non-linear process.

For example, for applications in telecommunications, this energy is 2×0.8 eV=1.6 eV. There is an extensive literature in which it has been demonstrated that the material of choice is AlGaAs with an aluminium molar fraction of less than 18%. This material has a strong response of the Kerr type and a low 2-photon absorption.

It is also necessary to amplify the non-linear response by optical power confinement by introducing resonances.

Photonic crystal technology is well suited to non-linear switching as it allows unprecedented light confinement compared with other optical structures. Recently, a Japanese group (H. Oda el al., Applied Physics Letters 90, 231102 (2007)) succeeded in fabricating structures based on AlGaAs photonic crystals and demonstrated the Kerr effect.

This represents a major advantage since photonic crystals enable the non-linearity to be enhanced, while lowering the required optical power, and brings said non-linearity back up to values compatible with the optical signals used for applications in telecommunications.

However, this approach has a major drawback, since the Al/Ga/As-based alloy is a material which is unstable when exposed to oxygen, this instability being amplified by the nanostructuring of the material. This becomes even more serious when the aluminium fraction increases, thus resulting in low optical flux resistance due to the surface defects generated by the oxidation.

### SUMMARY OF THE INVENTION

In this context, the present invention proposes to use a novel type of semiconductor material in which it is possible to produce photonic crystal structures having excellent properties in terms of third-order non-linearity but not exhibiting two-photon absorption in the operating wavelength band of the optical device integrating it.

More precisely, one subject of the present invention is an optical device operating within a wavelength range centred on a reference wavelength (λ₀) and delivering an output signal upon injection of a first optical signal, characterized in that it comprises a photonic crystal structure having a semiconductor substrate and at least one layer of semiconductor material having, at least locally, an array of features arranged so as to form a resonant optical cavity, said material of the semiconductor layer being a gallium/indium/phosphorus alloy not exhibiting two-photon absorption within the operating wavelength range of said device.

According to one embodiment of the invention, the device comprises an array of optical cavities, enabling the optical output signal to be amplified.

According to one embodiment of the invention, the device comprises, in said semiconductor layer, a first waveguide and at least one optical cavity coupled to said first waveguide, at least a first optical signal having a number of carrier frequencies and being injected into said first waveguide, coupled to the cavity, said cavity providing a filter function and having a resonant frequency such that said frequency enables an optical signal at said frequency to be extracted from said cavity.

According to one embodiment of the invention, an information-carrying first optical signal is injected into said waveguide along a first direction of propagation, a control second optical signal comprising a pulse train and being injected into said waveguide along a second direction of propagation opposite said first direction so as to be able to select information contained in said first optical signal.

According to one embodiment of the invention, the device comprises a second waveguide coupled to the optical cavity, an information-carrying first optical signal comprising a number of carrier frequencies and being injected into said first waveguide, a control second optical signal comprising a pulse train and being injected into the second waveguide so as to be able to select information contained in said first optical signal.

According to one embodiment of the invention, the device comprises a photodetector coupled to said second waveguide at the opposite end to that via which the control signal is injected, so as to recover the optical output signal.

According to one embodiment of the invention, the first and second waveguides comprise filters based on photonic crystals and make it possible to block the control signal.

According to one embodiment of the invention, the device comprises a series of cavities or an array of cavities and a series of second waveguides for addressing a series of control signals.

According to one embodiment of the invention, the device comprises a series of photodetectors for recovering a series of output signals upon injection of an optical input signal.

According to one embodiment of the invention, the device comprises an array of optical cavities, enabling the interaction of the optical output signal to be amplified.

According to one embodiment of the invention, the device comprises, on the surface of a GaAs substrate, a multilayer film comprising the following layers:
a GaInP layer;
a GaAs sacrificial layer; and
the layer of Ga/In/P alloy semiconductor material comprising the periodic structure.

According to one embodiment of the invention, the sacrificial layer is locally exposed beneath the layer of semiconductor material comprising the periodic structure.

According to one embodiment of the invention, the layer of semiconductor material comprises locally an absence of periodic features so as to create one or more waveguides, or one or more cavities.

According to one embodiment of the invention, the periodic features are holes.

### BRIEF DESCRIPTION OF THE DRAWINGS

The invention will be better understood and other advantages will become apparent on reading the following description given by way of non-limiting example and in conjunction with the appended figures, in which:

FIG. 1 shows schematically an interferometer for organizing the routing of information by optical control on an optical carrier;

FIG. 2 illustrates the transmission of an optical signal consisting of a 10-picosecond pulse in a waveguide produced in a GaAs-based photonic crystal and in a GaInP-based photonic crystal;

FIG. 3 illustrates the variation in transmission within a photonic crystal waveguide made from GaInP as a function of the propagation wavelength of an optical wave, for various power levels;

FIGS. 4a and 4b illustrate a top view and a sectional view of an example of a photonic crystal structure used in a device according to the invention;

FIGS. 5a and 5b illustrate different views of an optical device according to the invention comprising at least one waveguide coupled to a cavity produced in a photonic-crystal membrane structure;

FIG. 6 illustrates a configuration consisting of two waveguides and one cavity, these being used in an optical device according to the invention; and

FIG. 7 illustrates an example of an architecture that combines several functional elements so as to produce the optical package header recognition function.

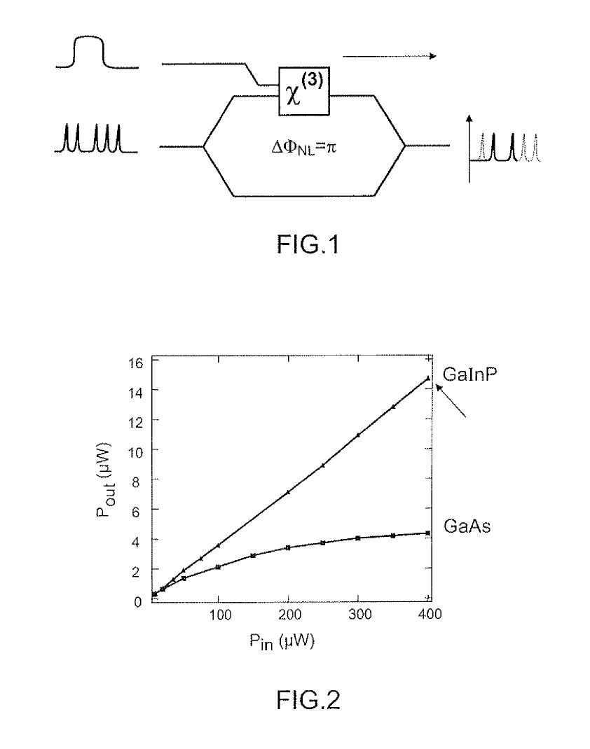

### DETAILED DESCRIPTION

The present invention provides an optical device integrating a photonic crystal structure produced in a novel type of semiconductor material, in this case a GaInP alloy (lattice matched on GaAs) and preferably satisfying the following chemical formula:

Ga_{0.51}In_{0.49}P.

It has been demonstrated by the Applicant that this material has the same non-linear properties as AlGaAs having a high Al content, while still being perfectly stable and resistant to high optical flux levels.

This is a key advantage, making it possible to obtain, starting from an albeit modest optical power level, very high optical intensities in accordance with the photonic crystals while not exhibiting two-photon absorption deleterious for the targeted applications.

Firstly, the bandgap, i.e. the energy gap between the valence band and the conduction band, of GaInP (specifically Ga_{0.51}In_{0.49}P)—a direct-bandgap semiconductor—is about 1.9 eV, i.e. a negligible, or even zero, two-photon absorption for optical signals in the telecom band (energy 0.8 eV<1.9 eV/2).

This is notably illustrated in FIG. 2, which shows the variation in transmission of a photonic crystal structure made of a GaAs-type semiconductor material and a GaInP-type semiconductor material according to the invention. More precisely, the transmission is illustrated by the output power Pₒᵤₜ as a function of the input power Pᵢₙ of a waveguide produced in the structure, this power being expressed in microwatts.

Two-photon absorption results, in the case of GaAs, in an output power threshold effect, whereas GaInP does not have the absorption problem resulting in a saturation effect.

Moreover, the Applicant has experimentally demonstrated properties obtained using a photonic crystal waveguide produced within a photonic-crystal-on-GaInP structure.

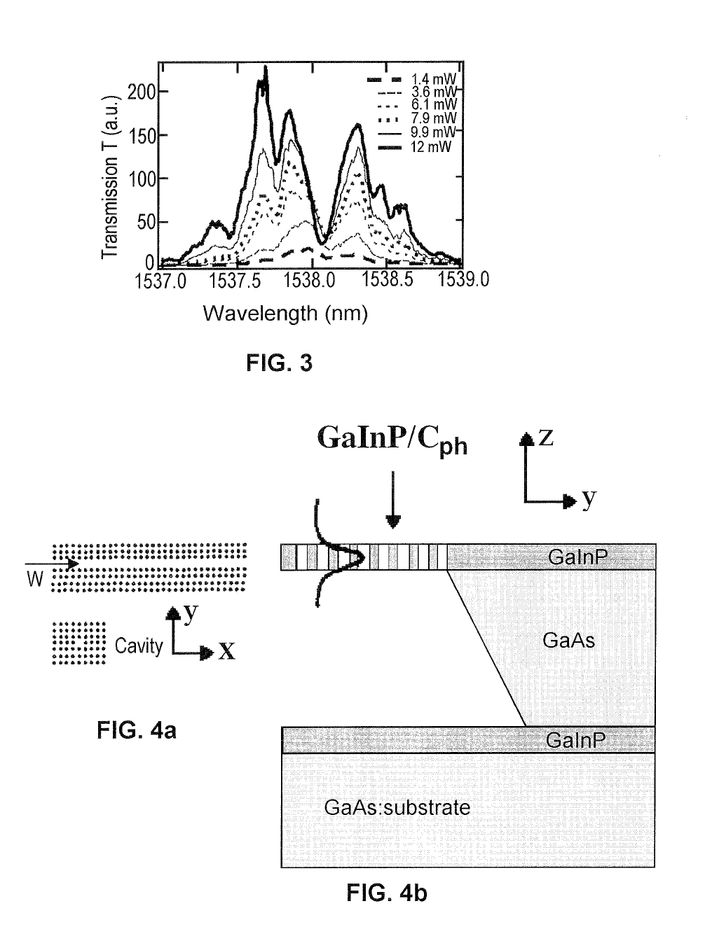

In this regard, FIG. 3 illustrates the spectrum of the transmitted pulse, which shows strong spectral broadening, proving phase self-modulation, and a minimum at the centre of the plot associated with a non-linear phase change of the order of π, attesting to the non-linear properties of the material, as described in the article: H. Oda el al. Applied Physics Letters 90, 231102 (2007).

We describe below examples of optical devices according to the invention, having a membrane structure in which photonic crystals are produced that comprise one or more microcavities and one or more waveguides, and notably examples of optical devices for carrying out optical switching functions.

In general, photonic crystals are structures having a dielectric index that varies periodically on the scale of the wavelength, along one or more directions in space. Compared with three-dimensional crystaline structures, it has been demonstrated that a two-dimensional structure could be particularly advantageous. In this case, crystals are produced in a thin semiconductor guiding layer, thereby allowing better control and easier production technology, compatible with conventional microelectronics technologies. A very thin layer, thus constituting a membrane, is isolated, which membrane may typically have a thickness h ranging from around 150 nanometres to 300 nanometres for applications aimed at the spectral range between about 1 micron and 1.6 microns. By a simple scale law, this thickness is adjusted so as to extend the application to other spectral ranges; typically, this thickness may be between 0.1 and 0.3 times the wavelength.

By creating a break in such a periodic structure, for example by omission of certain holes, it becomes possible to create a photonic cavity within which the energy remains stored. Such a cavity can then provide a filter function with resonance modes, or else may constitute a laser cavity emitting in a plane perpendicular to the plane of the membrane.

FIG. 4a illustrates a top view of a waveguide W and a cavity Ca produced by the absence of features within a photonic crystal structure Cₚₕ produced in a thin GaInP layer.

FIG. 4b illustrates a sectional view of this thin layer in which the various desired functions are intended to be carried out: resonant cavity, waveguide, filter, etc.

For this, a multilayer film comprising the following layers is produced on the surface of a GaAs substrate:
a GaInP stop layer;
a GaAs sacrificial layer;
the GaInP layer.

It should be noted that the stop layer is optional.

All the functions may be produced by local etching of the GaInP layer. The membrane is exposed by wet etching of the GaAs sacrificial layer, the etch stopping on the lower GaInP layer.

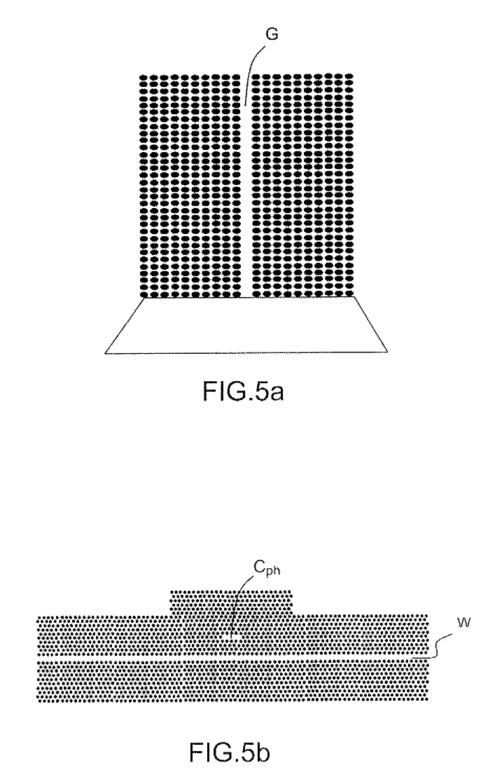

FIGS. 5a and 5b illustrate photographs of the photonic crystal structure used in an optical device according to the invention, comprising notably at least a waveguide W and a cavity Cₚₕ that are mutually coupled.

In this type of device, a carrier wave signal is injected into one end of the waveguide. The cavity, since it is coupled to the waveguide and therefore fed with the carrier wave signal, makes it possible to filter out only the frequencies corresponding to the resonant frequencies of the cavity. Following an optical control pulse, this frequency is shifted and the gate opens or closes depending on the frequency of the optical signal carrier relative to that of the cavity.

One embodiment of this structure is an “in-line” configuration, such that the structure transmits at resonance.

Another embodiment consists in the use of several cavities to increase the “open” state/“closed” state signal ratio (also called the extinction factor). The frequency of the optical cavity may be different from that of the signal, so as to prevent crosstalk. In this case, the cavity is designed so as to have two resonant frequencies.

One of the major advantages of the present invention is the ability to integrate all the functions necessary for operation of the device into the GaInP layer.

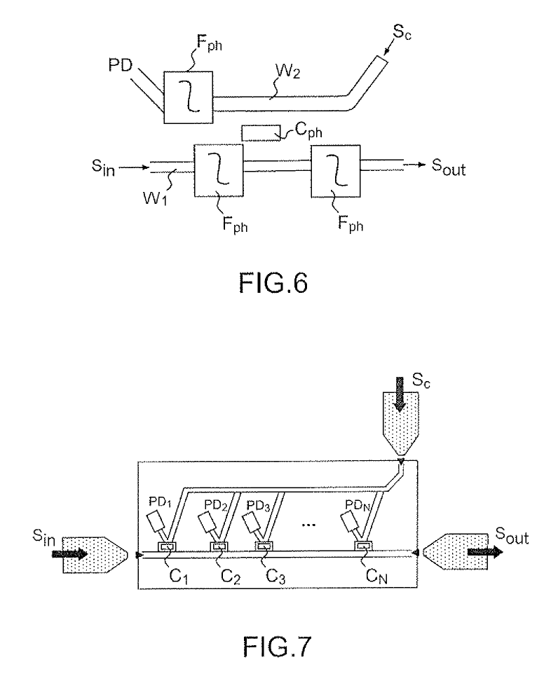

In this regard, FIG. 6 illustrates an embodiment comprising two waveguides produced by a break in periodicity. A first input signal Sᵢₙ is injected into a first waveguide W₁ and is coupled to the cavity Cₚₕ (alternatively, it could be coupled to an array of cavities).

A control signal S_{c} is injected at the same time into a second waveguide W₂, this second waveguide also serving to recover the output signal for coupling with the photonic cavity, for example a photodetector PD.

Advantageously, the functions of the photonic crystal filter Fₚₕ are band-pass filter functions, intended to block the control signal, and may also be designed within the periodicity break so as to prevent any undesirable signal return liable to interfere with the useful signals.

FIG. 7 illustrates another embodiment of optical device according to the invention, comprising a series of photonic cavities, a series of photodetectors and a series of second waveguides, these various components being coupled with an optical signal carrying packets of information, which it is necessary to select with various control signals injected into the series of second waveguides.

The device involves a complex photonic-crystal circuit with inputs/outputs based on the present invention. Starting with an input signal or carrier transmitting a signal at the wavelength λₛ, it is possible to make said signal wave interfere with an optical control wave at the wavelength λ_{c} so as to address a packet of optical signal information.

Thus, photonic-crystal-based optical gates C₁, C₂, . . . , C_{N} are used to couple input signals Sᵢₙ and control signals S_{c} to waveguides designed so as to produce an interferometer architecture with an optical output signal Sₒᵤₜ. The waveguides are produced within membrane-type photonic crystals, by modification of the periodic structure, typically produced by the absence of features. The device also includes photodetectors PD₁, PD₂, . . . , PD_{N}.

A series of photodetectors is coupled to the series of second waveguides, the second waveguides being angled, as shown in FIG. 6.

Typically, the entire footprint of such a device may be extremely compact, it being possible for the length of the device illustrated in FIG. 7 to be around a few millimetres.

An alternative to this embodiment is a device in which the series of cavities comprises an array of cavities and not a single cavity.

What is claimed is:

1. Optical device operating within a wavelength range centred on a reference wavelength (λ₀) and delivering an output signal upon injection of a first optical signal, comprising a photonic crystal structure having a semiconductor substrate and at least one layer of semiconductor material having, at least locally, an array of features arranged so as to form a resonant optical cavity, said material of the semiconductor layer being a gallium/indium/phosphorus alloy not exhibiting two-photon absorption within the operating wavelength range of said device.

2. Optical device according to claim 1, comprising an array of optical cavities, enabling the optical output signal to be amplified and the bandwidth to be broadened.

3. Optical device according to either of claims 1 or 2, comprising in said semiconductor layer, a first waveguide and at least one optical cavity coupled to said first waveguide, at least a first optical signal having a number of carrier frequencies and being injected into said first waveguide, coupled to the cavity and having a resonant frequency such that said frequency enables an optical signal at said frequency to be extracted from said cavity.

4. Optical device according to claim 1, in which an information-carrying first optical signal is injected into said waveguide along a first direction of propagation, a control second optical signal comprising a pulse train and being injected into said waveguide along a second direction of propagation opposite said first direction so as to be able to select information contained in said first optical signal.

5. Optical device according to claim 1, comprising a second waveguide coupled to the optical cavity, an optical information-carrying first optical signal comprising a number of carrier frequencies and being injected into said first waveguide, a control second optical signal comprising a pulse train and being injected into the second waveguide so as to be able to select information contained in said first optical signal.

6. Device according to claim 5, comprising a photodetector coupled to said second waveguide at the opposite end to that via which the control signal is injected, so as to recover the optical output signal.

7. Optical device according to either of claims 5 and 6, in which the first and second waveguides comprise photonic-crystal-based band-pass filters.

8. Optical device according to one of claims 4 to 6, comprising a series of cavities or an array of cavities and a series of second waveguides for addressing a series of control signals.

9. Optical device according to claim 8, comprising a series of photodetectors for recovering a series of output signals upon injection of an optical input signal.

10. Optical device according to one of claims 1 or 2, comprising an array of optical cavities, enabling the interaction of the optical output signal to be amplified.

11. Optical device according to one of claims 1 or 2, comprising on the surface of a GaAs substrate, a multilayer film comprising the following layers:
a GaInP layer;
a GaAs sacrificial layer; and
the layer of Ga/In/P alloy semiconductor material comprising the periodic structure.

12. Optical device according to claim 11, in which the sacrificial layer is locally exposed beneath the layer of semiconductor material comprising the periodic structure.

13. Optical device according to one of claims 1 or 2, in which the layer of semiconductor material comprises locally an absence of periodic features so as to create one or more waveguides, or one or more cavities.

14. Optical device according to one of claims 1 or 2, in which the periodic features are holes.
